(19) United States
(12) Patent Application Publication
(10) Pub. No.: US 2026/0107779 A1
(43) Pub. Date: Apr. 16, 2026

(54) ELECTROSTATIC DISCHARGE PERFORMANCE FOR POWER CLAMP CIRCUIT

(71) Applicant: Taiwan Semiconductor Manufacturing Company, Ltd., Hsinchu (TW)

(72) Inventors: Lin-Yu Huang, Hsinchu (TW); Shih-Fan Chen, Hsinchu City (TW); Sheng-Fu Hsu, Hsinchu (TW)

(21) Appl. No.: 18/917,063

(22) Filed: Oct. 16, 2024

(51) Int. Cl. H01L 23/60; H01L 23/64; H01L 25/11; H01L 29/20; H01L 29/417; H01L 29/778

(52) U.S. Cl. CPC H10W 42/60; H10D 30/47; H10D 62/85; H10D 64/257; H10W 44/401; H10W 90/00

(57) ABSTRACT

Some embodiments relate to an integrated device, including: a resistor and capacitor structure coupled in series between a high voltage wire and a low voltage wire, the resistor and capacitor structure having a first node electrically coupled to a resistor and a capacitor; a transistor comprising a first source/drain terminal coupled to the high voltage wire, a second source/drain terminal coupled to the low voltage wire, and a gate terminal; and a diode coupled between the gate terminal and either the high voltage wire or the low voltage wire.

### BACKGROUND

Integrated circuits (ICs) comprise a variety of circuit components that perform functions throughout the circuit. Circuit components utilize voltage differences supplied by high voltage wires and low voltage wires to perform logical operations, store and access memory, and receive and transmit energy. External sources of current and voltage (e.g., electrostatic discharge (ESD) or the like), however, may introduce different voltage levels that the circuit components may be damaged by.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, and 1D illustrate circuit schematics of some embodiments of an active power clamp with a diode between a gate terminal and a voltage wire.

FIGS. 2A and 2B illustrate top-down views of an active power clamp with a diode between a gate terminal and a low voltage wire where a first node between a capacitor and a resistor is coupled directly to a gate terminal of a transistor.

FIGS. 3A and 3B illustrate top-down views of an active power clamp with a diode between the gate terminal and a high voltage wire where the first node between the capacitor and the resistor is coupled directly to the gate terminal of the transistor.

FIGS. 4A and 4B illustrate top-down views of an active power clamp with a diode between the gate terminal and the low voltage wire where the first node between the capacitor and the resistor is coupled to an inverter circuit, where an odd number of inverter circuits are coupled in series between the first node and the gate terminal.

FIGS. 5A and 5B illustrate top-down views of an active power clamp with a diode between the gate terminal and the high voltage wire where the first node between the capacitor and the resistor is coupled to an inverter circuit, where an even number of inverter circuits are coupled in series between the first node and the gate terminal.

FIG. 6 illustrates a cross-sectional view of an active power clamp with a diode between the gate terminal and the low voltage wire where a capacitor is within an interconnect structure over the resistor, diode, and transistor, and wherein the resistor, diode and transistor comprise a channel layer and an active layer.

FIG. 7 illustrates a cross-sectional view of an active power clamp with a diode between the gate terminal and the low voltage wire where a capacitor is within an interconnect structure over the resistor, diode, and transistor.

FIGS. 8A-12 illustrate a series of cross-sectional views of some embodiments of a method of forming an active power clamp with a diode between the gate terminal and a voltage wire.

FIG. 13 illustrates a flowchart of some embodiments of a method of forming an active power clamp with a diode between the gate terminal and a voltage wire.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

Integrated devices comprise a high voltage wire and a low voltage wire. During operation, the high voltage wire supplies a first supply voltage (VDD) and the low voltage wire supplies a second supply voltage (VSS) less than the first supply voltage VDD. The high voltage wire and the low voltage wire are coupled to circuit components (e.g., passive circuit components, transistors, operational amplifiers, or the like) in the integrated device. The difference in the voltage at the high voltage wire and the low voltage wire is specific to the device and the type of circuit components used in the integrated device.

Electrostatic discharge (ESD) from sources external to the integrated device result in the affected component or the high or low voltage wires having a much higher or lower voltage than during normal operation. The levels of voltage caused by ESD may exceed the nominal voltages of the circuit components used in the integrated device, resulting in damage to the affected components. The damaged components result in lowered performance of the integrated device, or failure of the circuit to operate.

One method of reducing the impact of ESD on the voltage levels of the integrated device is to use power clamps. In some embodiments, power clamps comprise a series RC or CR circuit coupled between the high voltage wire and the low voltage wire, and a transistor with a first source/drain terminal coupled to the high voltage wire and a second source/drain terminal coupled to the low voltage wire. In some embodiments, a gate terminal of the transistor is coupled directly to a first node coupled between the capacitor and the resistor. In other embodiments, one or more inverter circuits are coupled in series between the first node and the gate terminal.

The power clamp conducts unexpected ESD current from a positive (e.g., an unexpected increase in voltage) ESD event at the high voltage wire or a positive (e.g., an unexpected increase in voltage) ESD event at the low voltage wire, discharging the ESD current to mitigate damage to the circuit components. However, power clamp circuits of the configuration described above may be slow to discharge negative (e.g., an unexpected decrease in voltage) ESD events at the high voltage wire. The discharge of the negative ESD event is prolonged further in active voltage clamps where the transistor has a floating base terminal or is an n-type high electron mobility transistor (nHEMT) with no body diode. Therefore, a device that maintains the effectiveness of the active power clamp while enhancing operation during negative ESD events is desirable.

The present disclosure provides for a diode coupling the gate terminal of the transistor to either the low voltage wire or the high voltage wire of the device, depending on the type of the transistor used within the end stage of the active power clamp. For n-type transistors, the diode is configured such that a cathode of the diode is coupled to the gate terminal and an anode of the diode is coupled to the low voltage wire. For p-type transistors, the diode is configured such that the cathode of the diode is coupled to the high voltage wire and the anode of the diode is coupled to the gate terminal. During a negative ESD event at the high voltage wire, the high voltage wire is driven to a substantially lower voltage than the low voltage wire (VDD«VSS). The sudden decrease in VDD results in a rapid response from capacitor side of the RC circuit, driving the gate terminal low (for active power clamps using an n-type transistor) or high (for active power clamps using a p-type transistor). In embodiments without a diode, the change in voltage at the gate results in the transistor maintaining a “cut-off” state. The “cut-off” state results in the transistor not turning on until the gate-to-drain voltage V_{GD} either rises (for an n-type transistor) to a greater voltage than the threshold voltage V_{TH} or falls (for a p-type transistor) below the threshold voltage V_{TH}. The change in voltage after the negative ESD event is based on the RC delay of the series RC circuit.

In embodiments with the diode, the sudden change in VDD activates the diode, resulting in the gate terminal having a voltage equal to VSS minus the threshold voltage of the diode (for an n-type transistor) or having a voltage equal to VDD plus the threshold voltage of the diode (for a p-type transistor). The immediate voltage resulting from the activation of the diode bypasses a portion (e.g., approximately between 20% to 50%) of the RC delay in the power clamp circuit, resulting in an increased speed in the activation of the transistor and the discharge of the ESD. The increase speed of the discharge of the ESD reduces the amount of damage taken by logic components of the circuit.

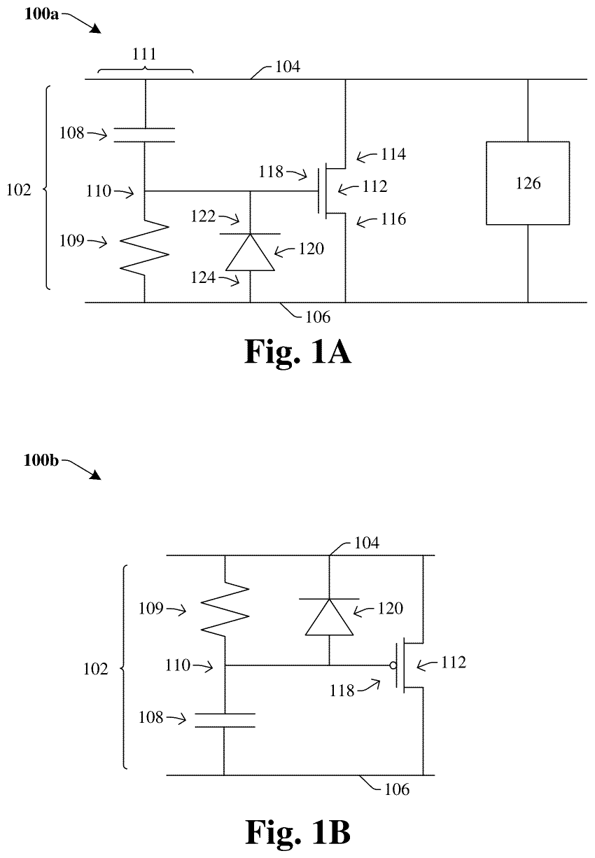

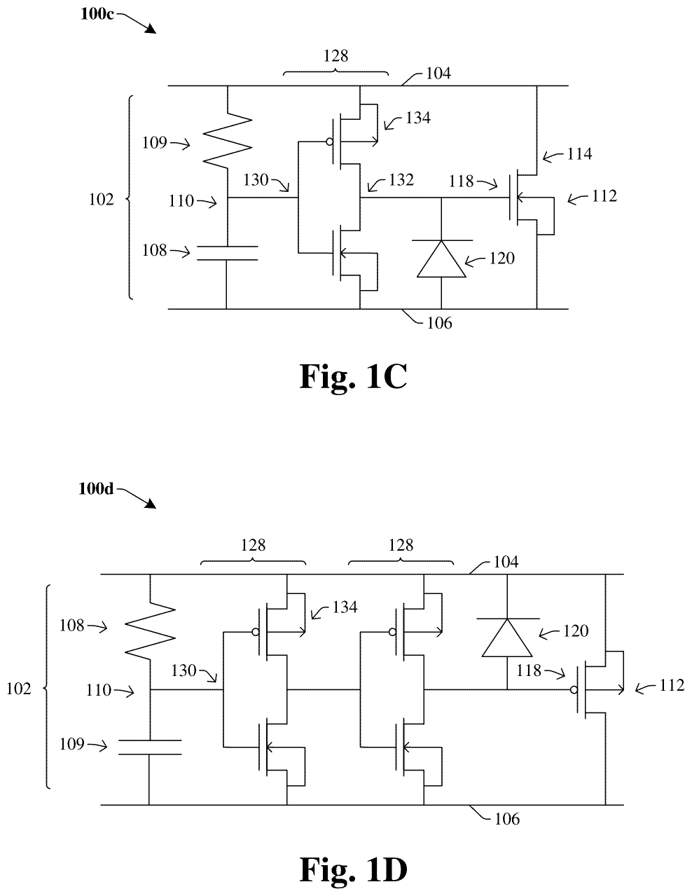

FIGS. 1A, 1B, 1C, and 1D illustrate circuit schematics 100a, 100b, 100c, 100d of some embodiments of an active power clamp with a diode between a gate terminal and a voltage wire.

As shown in the circuit schematic of FIG. 1A, a power clamp 102 is coupled between a high voltage wire 104 and a low voltage wire 106. The power clamp 102 comprises a capacitor 108 coupled between the high voltage wire 104 and a first node 110, a resistor 109 coupled between the low voltage wire 106 and the first node 110. The combination of the resistor 109 and the capacitor 108 is also referred to as a resistor capacitor structure 111. The power clamp 102 further comprises a transistor 112 with a first source/drain terminal 114 coupled to the high voltage wire 104, a second source/drain terminal 116 coupled to the low voltage wire 106, and a gate terminal 118 coupled to the first node 110. Source/drain region(s) may refer to a source or a drain, individually or collectively dependent upon the context. A diode 120 has a cathode 122 coupled to the gate terminal 118 and an anode coupled to the low voltage wire 106.

The power clamp 102 is configured to prevent the voltage VDD of the high voltage wire 104 from rising above a first threshold and is configured to prevent the voltage VSS of the low voltage wire 106 from falling below a second threshold. In some embodiments, the first threshold is between approximately 1.5 and 5 volts, between 3.5 and 7 volts, between 5 volts and 10 volts, or within another similar range, and is chosen based on the function and performance characteristics of the corresponding circuit 126. In some embodiments, the second threshold is approximately 0 volts, and is chosen based on the function and performance characteristics of the corresponding circuit 126. If a voltage VDD rises above the first threshold or the voltage VSS falls below the second threshold for an extended period of time, circuit components within the corresponding circuit 126 may operate at an increased voltage and current, leading to increased temperatures, higher thermal resistance, and a potential for dielectric breakdown and damage to the circuit components.

The power clamp 102 discharges voltages exceeding the first or second threshold by activating the transistor 112 coupled between the high voltage wire 104 and the low voltage wire 106 until the designed difference between the voltage VDD and the voltage VSS is returned to. For example, in a positive ESD event (e.g., a higher voltage than the corresponding circuit 126 is designed for is suddenly introduced) at the high voltage wire 104, the voltage at the gate terminal 118 will rise above the threshold voltage V_{TH} of the transistor, activating the transistor 112 and discharging the ESD. As the ESD discharges, the voltage at the gate terminal 118 will lower until it is below the threshold voltage V_{TH} of the transistor 112, returning the transistor to the “cut-off” mode.

During a negative ESD event (e.g., a lower voltage than the corresponding circuit 126 is designed for is suddenly introduced at the high voltage wire 104), the high voltage wire 104 has a lower voltage VDD than the voltage VSS of the low voltage wire 106. The voltage at the gate terminal 118 is also reduced quickly. As the transistor 112 is an n-type device, the transistor channel conducts when the voltage at the gate terminal 118 is greater than the voltage threshold V_{TH} to turn on. In embodiments without the diode 120, the voltage at the gate terminal 118 will subsequently rise to the voltage VSS based on the RC delay of the circuit. The delayed activation of the transistor 112 may result in damage to circuit components in the corresponding circuit 126.

In embodiments with the diode 120, the negative ESD event at the high voltage wire 104 results in the voltage at the gate terminal 118 lowering below the voltage VSS at the low voltage wire, activating the diode 120. The activation of the diode 120 results in the voltage at the gate terminal 118 rising back to and being maintained at the voltage VSS minus the threshold voltage of the diode. Due to the drop in VDD, the resulting voltage at the gate terminal activates the transistor after a reduced delay compared to the delay of embodiments without the diode. In some embodiments, the delay is reduced by approximately between 20% and 50%, between approximately 25% and 55%, between approximately 15% and 45%, or within another similar range. The reduced delay after the negative ESD event results in the discharge of the excess charge at the high voltage wire in a faster time frame, mitigating the damage to the circuit components of the corresponding circuit 126.

As shown in the circuit schematic 100b of FIG. 1B, in some embodiments, the transistor 112 in the power clamp 102 is a p-type transistor. Further, the resistor 109 is coupled between the high voltage wire 104 and the first node 110, the capacitor 108 is coupled between the low voltage wire 106 and the first node 110, and the diode 120 is coupled between the high voltage wire 104 and the gate terminal 118. During a negative ESD event at the high voltage wire 104, the voltage VDD of the of the high voltage wire 104 suddenly decreases. In embodiments without the diode 120, there is a large delay relative to embodiments with the diode 120 in the voltage at the gate terminal 118 lowering enough to activate the transistor 112. That is, embodiments with the diode 120 lower the voltage at the gate terminal 118 to the decreased voltage VDD value plus the voltage threshold of the diode 120 when the voltage VDD decreases, resulting in the transistor 112 activating after a reduced delay compared to embodiments without the diode 120.

As shown in the circuit schematic 100c of FIG. 1C, in some embodiments, the power clamp 102 may further comprise an odd number of inverter circuits 128 (e.g., one inverter circuit, three inverter circuits, five inverter circuits, seven inverter circuits, etc.). The inverter circuits 128 comprise input nodes 130 coupled to the first node 110 (or an output node 132 of a preceding inverter circuit 128) and output nodes 132 coupled to the gate terminal 118 (or an input node of a subsequent inverter circuit 128. The odd number of inverter circuits 128 are configured to invert the signal at the first node 110 an odd number of times, coupling the gate terminal 118 of the transistor 112 to either the high voltage wire 104 or the low voltage wire 106 depending on the voltage at the first node 110. In embodiments with an odd number of inverter circuits 128 and the capacitor 108 coupled between the low voltage wire 106 and the first node 110, the transistor 112 is an n-type transistor (e.g., it conducts current when the voltage across the gate and a source/drain terminal is above a voltage threshold V_{TH}) and the diode is coupled between the low voltage wire 106 and the gate terminal 118.

During a positive ESD event at the high voltage wire 104, the RC delay of the resistor and capacitor results in the voltage at the input node 130 of the first inverter circuit 128 to be less than the voltage at the high voltage wire. This activates the p-type transistor 134 of the first inverter circuit, coupling the gate terminal 118 to the high voltage VDD and passing the excess current through the transistor 112. During a negative ESD event at the high voltage wire 104, the first source/drain terminal 114 of the transistor 112 is driven to the new voltage VDD, which is less than VSS. As the diode 120 maintains the voltage at the gate terminal 118 to be at least the voltage VSS minus the voltage threshold of the diode, the transistor 112 is turned on, passing current from the low voltage wire 106 to the high voltage wire 104.

As shown in the circuit schematic of FIG. 1D, in some embodiments, the power clamp 102 may further comprise an even number of inverter circuits 128 (e.g., two inverter circuits, four inverter circuits, six inverter circuits, eight inverter circuits, etc.). In embodiments with an even number of inverter circuits 128 and the capacitor 108 coupled between the low voltage wire 106 and the first node 110, the transistor 112 is a p-type transistor (e.g., it conducts current when the voltage across the gate and a source/drain terminal is below a voltage threshold V_{TH}) and the diode is coupled between the high voltage wire 104 and the gate terminal 118.

During a positive ESD event at the high voltage wire 104, the RC delay of the resistor 109 and the capacitor 108 results in the voltage at the input node 130 of the first inverter circuit 128 to be less than the voltage at the high voltage wire. This activates the p-type transistor 134 of the first inverter circuit. Due to the even number of inverter circuits 128, the gate terminal 118 is coupled to the low voltage wire 106, activating the transistor 112 and passing the current from the high voltage wire 104 to the low voltage wire 106 through the transistor 112. During a negative ESD event at the high voltage wire 104, the first source/drain terminal 114 of the transistor 112 is driven to the new voltage VDD, which is less than VSS. As the diode 120 maintains the voltage at the gate terminal 118 to be at no more than the voltage VDD plus the voltage threshold of the diode, the transistor 112 is turned on, passing current from the low voltage wire 106 to the high voltage wire 104.

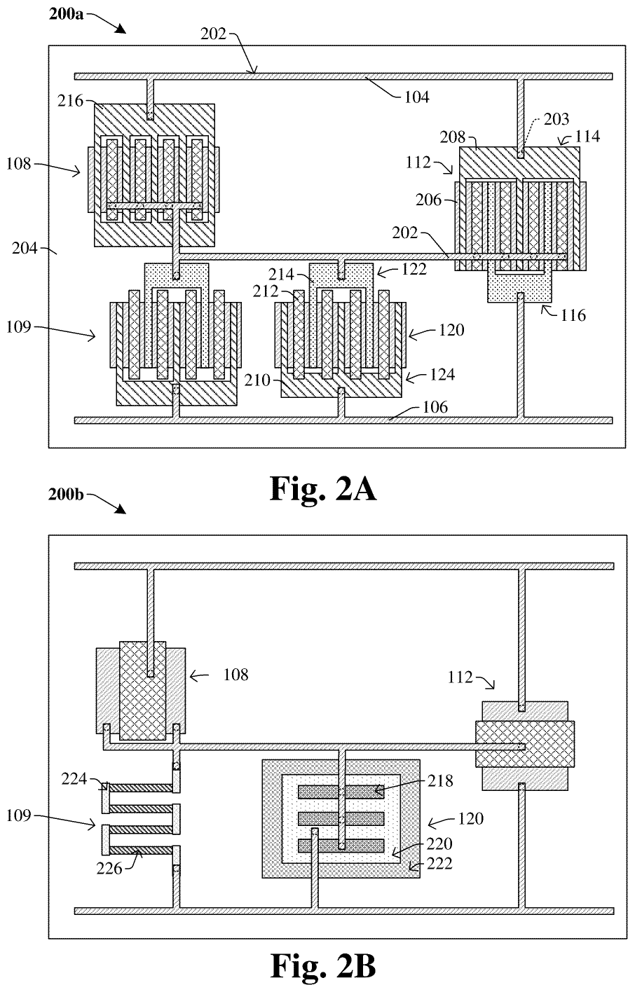

FIGS. 2A and 2B illustrate top-down views 200a, 200b of an active power clamp with a diode between a gate terminal and a low voltage wire where a first node between a capacitor and a resistor is coupled directly to a gate terminal of a transistor.

As shown in the top-down view 200a of FIG. 2A, in some embodiments, the transistor 112 of the circuit shown in FIG. 1A is a high electron mobility transistor (HEMT) on a substrate 204. An interconnect structure 202 comprising the high voltage wire 104 and the low voltage wire 106, as well as a plurality of contacts 203 coupled to terminals of the diode 120, the transistor 112, the capacitor 108, and the resistor 109. The interconnect structure 202 further couples the first node 110 and the diode 120 to the gate terminal 118. In some embodiments, the diode 120, capacitor 108, and resistor 109 are formed using the same active layers 206 and metal layers 208 as the transistor 112. For example, in some embodiments, the resistor 109 is a two-dimensional electron gas (2DEG) type resistor, and the capacitor 108 is an HEMT device with the source/drain terminals 216 coupled together to form one terminal of the capacitor 108.

In some embodiments, the diode 120 comprises an HEMT transistor with a third source/drain terminal 210 and a gate terminal 212 coupled together to form the anode 124, while a fourth source/drain terminal 214 forms the cathode 122. The third source/drain terminal 210 and the fourth source/drain terminal 214 may comprise a number of fingers approximately between 2 and 100. The aspect ratio (e.g., the ratio of the length and width of the active region of the diode) may be between 0.02 and 100. In some embodiments, the active layers 206 of the diode 120 is or comprises a combination of two or more of a binary III/V semiconductor material, a ternary III/V semiconductor material, silicon carbide (SiC), or the like. The active layers 206 are configured to form a 2DEG that extends beneath fingers of the third source/drain terminal 210 and fingers of the fourth source/drain terminal 214.

As shown in the top-down view 200b of FIG. 2B, in some embodiments, the transistor 112 shown in the circuit schematic 100a of FIG. 1A is a metal-oxide-semiconductor field effect transistor (MOSFET), or another type of transistor. Further, in some embodiments, the capacitor 108 is a metal-oxide-semiconductor (MOS) type device with the source/drain terminals 216 coupled together to form one terminal of the capacitor. In other embodiments, the capacitor 108 is a varactor, a metal-insulator-metal (MIM) type capacitor, a metal-oxide-metal (MOM) type capacitor, or another variant of capacitor.

In some embodiments, the diode 120 is a silicon type diode, where the anode 124 and cathode 122 comprise a plurality of first doped regions 218 surrounded by a second doped region 220 within a doped well 222. In some embodiments, the plurality of first doped regions 218 are positively doped, the second doped region 220 is negatively doped, and the doped well 222 is negatively doped. In other embodiments, the plurality of first doped regions 218 are negatively doped, the second doped region 220 is positively doped, and the doped well 222 is positively doped. In yet other embodiments, the first doped regions 218 and the second doped region 220 are a first doping type, and the doped well 222 is a second doping type different from the first doping type, and a first terminal (e.g., one of the cathode 122 or the anode 124) of the diode 120 is coupled to the doped well 222 while a second terminal (e.g., the other of the cathode 122 or the anode 124) is coupled to one of the first doped regions 218 or the second doped region 220.

In some embodiments, the resistor 109 is a sheet resistor, a thin film resistor, or another type of resistor. In some embodiments, the resistor 109 comprises a plurality of conductive segments 224 extending between a plurality of insulative segments 226. In some embodiments, the resistor 109 comprises one or more of tantalum nitride (TaN), titanium nitride (TiN), oxide diffusion (OD) regions covered in a resist protective oxide (RPO), polysilicon (PO) regions covered in the RPO, doped wells, silicon chromium (SiCr), or the like.

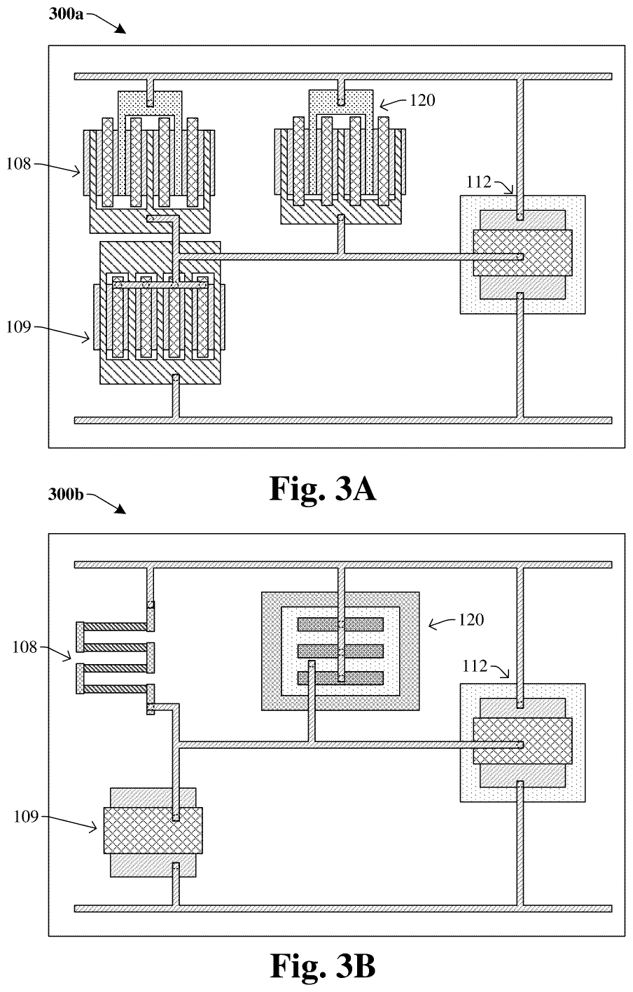

FIGS. 3A and 3B illustrate top-down views 300a, 300b of an active power clamp with a diode between the gate terminal and a high voltage wire where the first node between the capacitor and the resistor is coupled directly to the gate terminal of the transistor (see circuit schematic 100b of FIG. 1B). As shown in the top-down view 300a of FIG. 3A, in some embodiments the diode 120, the capacitor 108, and the resistor 109 are HEMT devices or are made using the same active layers 206 and metal layers 208 as the HEMT devices, as described in relation to FIG. 2A. The transistor 112 is a p-type transistor, and therefore is not an HEMT device and formed using a different technique. As shown in the top-down view 300b of FIG. 3B, in some embodiments, the transistor 112, the diode 120, the capacitor 108, and the resistor 109 are not HEMT devices, as described in relation to FIG. 2B.

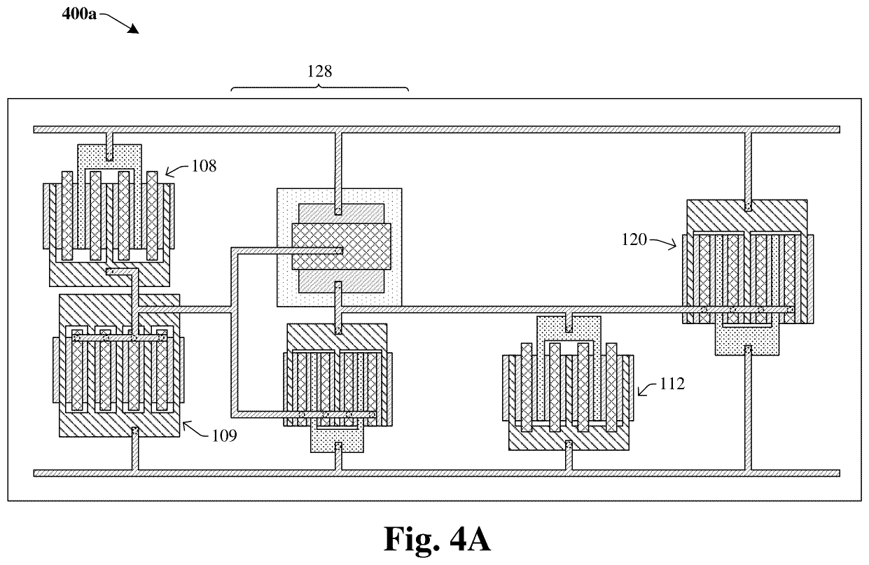

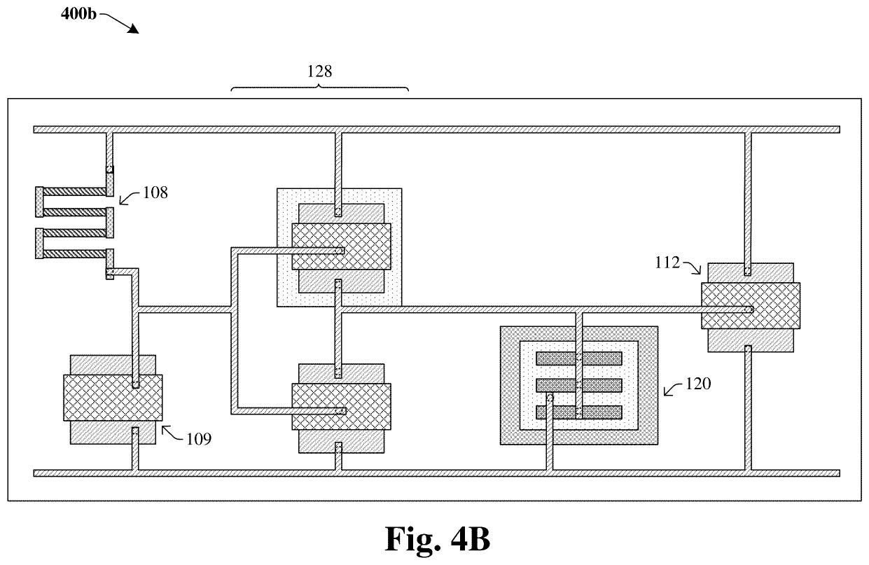

FIGS. 4A and 4B illustrate top-down views 400a, 400b of an active power clamp with a diode between the gate terminal and the low voltage wire where the first node between the capacitor and the resistor is coupled to an inverter circuit, where an odd number of inverter circuits are coupled in series between the first node and the gate terminal (see circuit schematic 100c of FIG. 1C). As shown in the top-down view 400a of FIG. 4A, in some embodiments the transistor 112, the diode 120, the capacitor 108, and the resistor 109 are HEMT devices or are made using the same active layers 206 and metal layers 208 as the HEMT devices, as described in relation to FIG. 2A. Additionally, in some embodiments, the inverter circuits 128 comprise an n-type HEMT transistor and a p-type transistor formed using a different technique, or both n-type and p-type transistors that are not HEMT transistors. As shown in the top-down view 400b of FIG. 4B, in some embodiments, the transistor 112, the diode 120, the capacitor 108, the resistor 109, and the transistors within the inverter circuits are not HEMT devices, as described in relation to FIG. 2B.

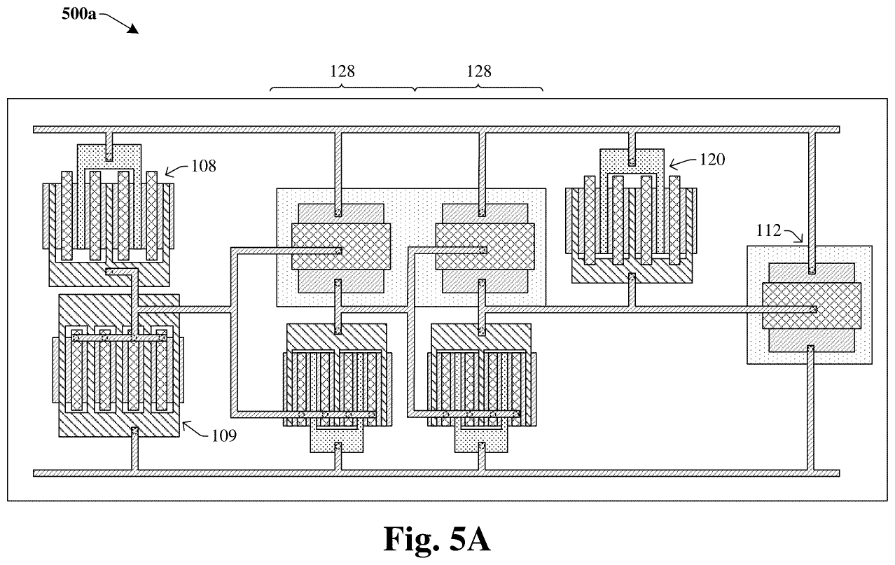

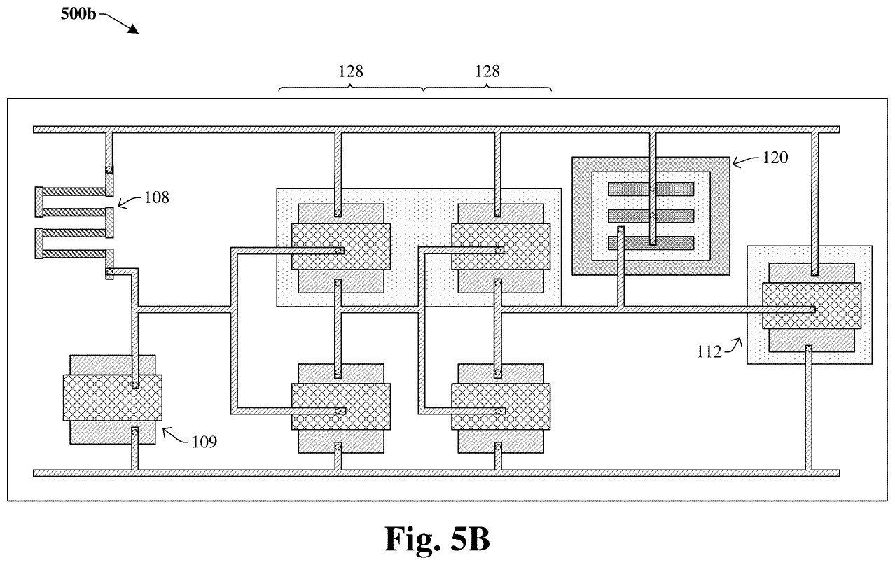

FIGS. 5A and 5B illustrate top-down views 500a, 500b of an active power clamp with a diode between the gate terminal and the high voltage wire where the first node between the capacitor and the resistor is coupled to an inverter circuit, where an even number of inverter circuits are coupled in series between the first node and the gate terminal. As shown in the top-down view 500a of FIG. 5A, in some embodiments the transistor 112, the diode 120, the capacitor 108, and the resistor 109 are HEMT devices or are made using the same active layers 206 and metal layers 208 as the HEMT devices, as described in relation to FIG. 2A. Additionally, in some embodiments, the inverter circuits 128 comprise an n-type HEMT transistor and a p-type transistor formed using a different technique, or both n-type and p-type transistors that are not HEMT transistors. As shown in the top-down view 500b of FIG. 5B, in some embodiments, the transistor 112, the diode 120, the capacitor 108, the resistor 109, and the transistors within the inverter circuits are not HEMT devices, as described in relation to FIG. 2B.

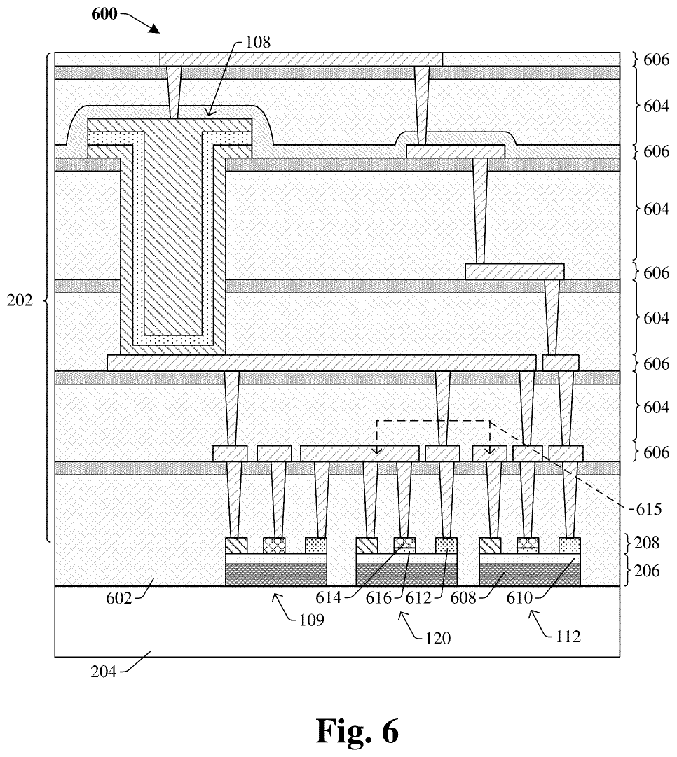

FIG. 6 illustrates a cross-sectional view 600 of an active power clamp with a diode between the gate terminal and the low voltage wire where a capacitor is within an interconnect structure over the resistor, diode, and transistor, and wherein the resistor, diode and transistor comprise HEMT devices or are formed using the same active layers and metal layers as the HEMT devices.

In some embodiments, the capacitor 108 is or comprises an MIM capacitor, an MOM capacitor, or another capacitor within the interconnect structure 202. In some embodiments, the capacitor 108 is separated from the substrate 204 by a portion of the interconnect structure 202 and an interlayer dielectric 602 surrounding the interconnect structure 202. The interconnect structure 202 comprises a plurality of wire levels 606 and a plurality of via levels 604 configured to form a plurality of conductive paths extending between the circuit components of the corresponding circuit (see 126 of FIG. 1A). In some embodiments, the resistor 109, the diode 120, and the transistor 112 all are HEMT devices or comprise active layers 206 and metal layers 208 formed concurrently with those of HEMT devices. In further embodiments, the inverter circuits (see 128 of FIGS. 1C and 1D) are also on the substrate 204, and the n-type transistors in the inverter circuits (see 128 of FIGS. 1C and 1D) are HEMT devices with active layers 206 and metal layers 208 formed concurrently with those of the transistor 112.

In some embodiments, the active layers 206 comprise a channel layer 608 that is or comprises silicon carbide (SiC) or a binary III/V semiconductor material (such as gallium nitride (GaN), gallium arsenide (GaAs) or the like) and a barrier layer 610 comprising a ternary III/V semiconductor material (such as aluminum gallium nitride (AlGaN), aluminum gallium arsenide (AlGaAs), or the like). In some embodiments, the metal layers 208 comprise a first metal layer 612 comprising the source/drain terminals of the transistor 112, the diode 120, and the resistor 109, and a second metal layer 614 comprising the gate terminals of the transistor 112, the diode 120, and the resistor. The second source/drain terminal 116 is coupled to the low voltage wire 106 through a first conductive path 615 extending through a first wire level 606.

The transistor 112 and the diode 120 further comprise a pGaN layer 616 (e.g., a layer of material comprising positively doped gallium nitride (GaN) or the like). The pGaN layer 616 results in the transistor 112 and the diode 120 having a “normally off” functionality, where the channels of the devices do not conduct when the gate terminals have a voltage of 0 volts. The pGaN layer 616 is omitted in the resistor 109, resulting in the resistor 109 having a “normally on” functionality. In some embodiments, the gate terminal of the resistor 109 is left floating or is omitted to maintain the “normally on” functionality. In other embodiments, the gate terminal of the resistor 109 is coupled to a grounding wire.

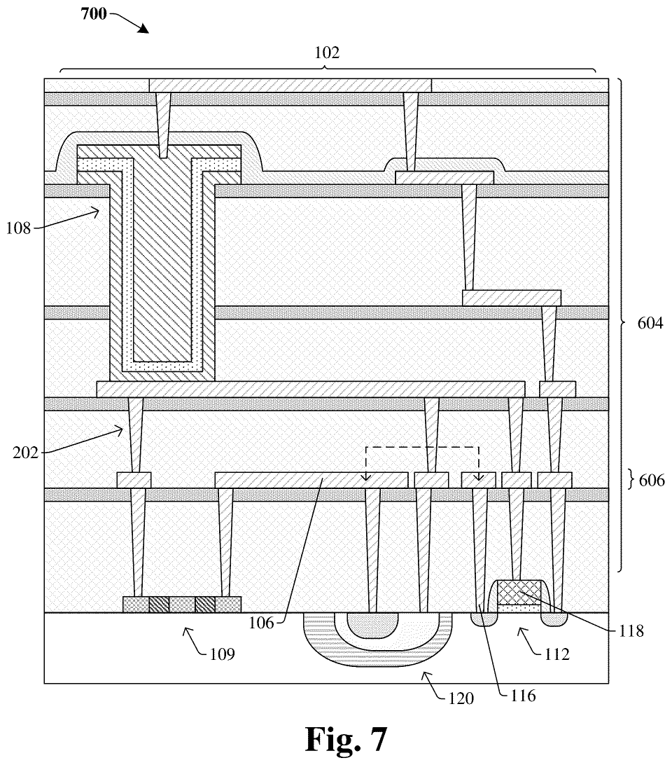

FIG. 7 illustrates a cross-sectional view 700 of a power clamp 102 with a diode 120 between the gate terminal 118 and the low voltage wire 106 where a capacitor 108 is within an interconnect structure 202 over the resistor 109, the diode 120, and the transistor 112. In some embodiments, the transistor 112, the resistor 109, the diode 120, and/or the capacitor 108 do not comprise HEMT devices or use the same active layers 206 or metal layers 208 as HEMT devices. Instead, the transistor 112 may comprise a MOSFET or the like, the diode 120 may comprise a plurality of doped regions or another variation, and/or the resistor may comprise one or more of a sheet resistor, and pinched resistor, a well resistor, or the like.

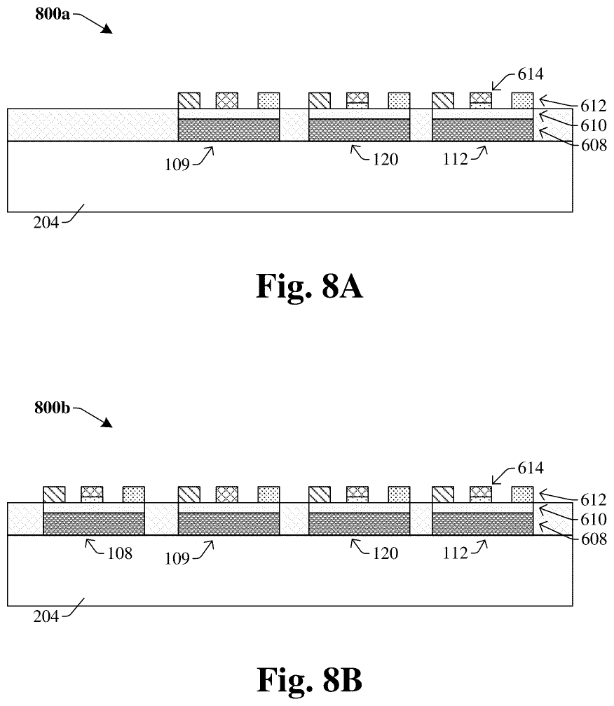

FIGS. 8-12 illustrate a series of cross-sectional views 800-1200 of some embodiments of a method of forming an active power clamp with a diode between the gate terminal and a voltage wire. Although FIGS. 8-12 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 800a of FIG. 8A, the transistor 112, the resistor 109, and the diode 120 are formed on the substrate 204. In some embodiments, the transistor, resistor 109, and the diode 120 are formed by etching the channel layer 608 and the barrier layer 610 to form openings corresponding to the space between the channel layer 608 and the barrier layer 610 corresponding to the transistor 112, the resistor 109, and the diode 120. The openings are then filled with an insulative layer (e.g., silicon dioxide (SiO₂) or the like). The first metal layer 612 is subsequently deposited over the barrier layer 610, after which portions of the first metal layer 612 corresponding to spaces between the source/drain terminals of the circuit components are removed. The gate terminals are subsequently formed by depositing a second metal layer 614 over the substrate and then removing portions of the second metal layer 614 that do not correspond to the gate terminals. In some embodiments, the channel layer 608 and the barrier layer 610, the first metal layer 612, and the second metal layer 614 are independently formed using one or more of physical vapor deposition (PVD), atomic layer deposition (ALD), chemical vapor deposition (CVD), a damascene process, or the like.

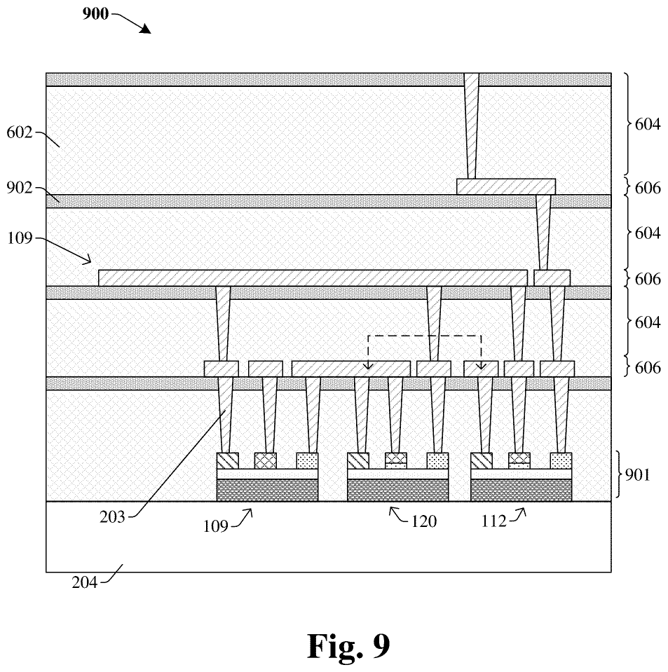

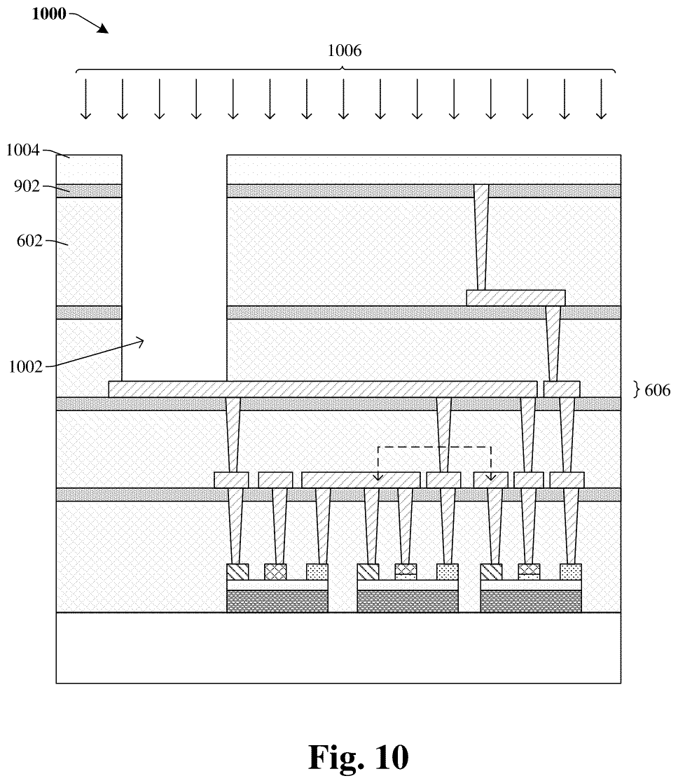

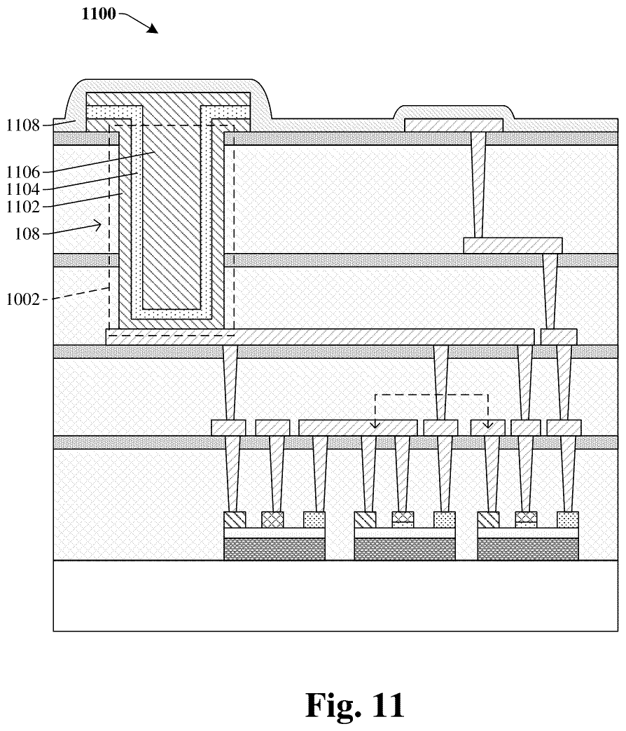

As shown in the cross-sectional view 800b of FIG. 8B, in some embodiments, the capacitor 108 is formed concurrently with the transistor 112 as an HEMT device. In other embodiments, the capacitor 108 is formed before or after the transistor 112 on the substrate using a different front-end-of-line (FEOL) technique. In yet other embodiments, the capacitor 108 is formed as part of a back-end-of-line (BEOL) process (see FIGS. 10-11). FIGS. 9-12 continue as if the capacitor will be formed as part of a BEOL process. It will be appreciated that the embodiments discussed in relation to FIGS. 2A-5B may be formed using a FEOL technique for the capacitor 108 and by omitting the formation of the capacitor 108 as shown in FIGS. 10-11.

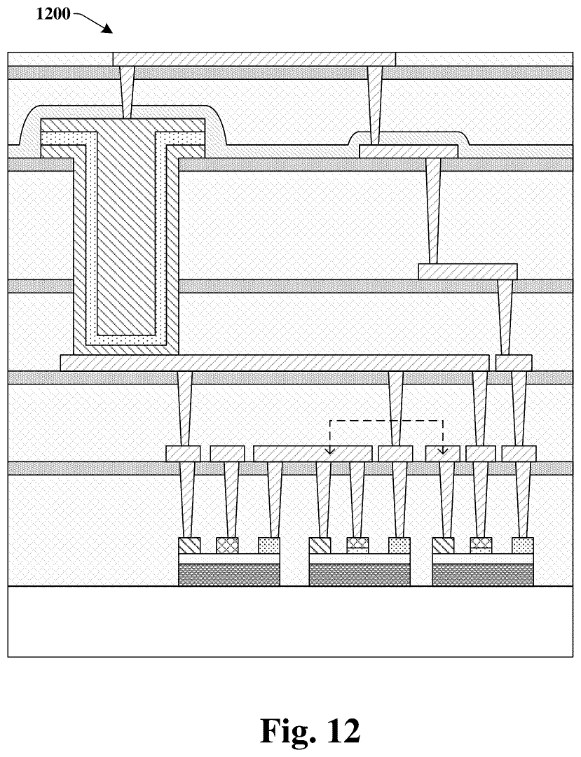

As shown in the cross-sectional view 900 of FIG. 9, a first portion of the interconnect structure 202 is formed over the substrate 204. The interconnect structure 202 is configured to couple the circuit components 901 to one another using a plurality of conductive paths and further comprises the high voltage wire 104 and the low voltage wire 106. In some embodiments, the low voltage wire 106 is formed within the first portion of the interconnect structure 202 and the high voltage wire 104 is formed within a second portion of the interconnect structure 202 after the formation of the capacitor (see FIGS. 11 and 12). The interconnect structure 202 is coupled to the circuit components 901 (e.g., the resistor 109, the diode 120, and the transistor 112) using a plurality of contacts 203.

In some embodiments, the interconnect structure 202 is formed by depositing a layer of the interlayer dielectric 602 over the substrate, depositing an etch stop layer 902, forming openings in the interlayer dielectric 602 and the etch stop layer 902, depositing a metal layer in the openings, and removing portions of the metal layer outside the openings to leave a via layer (or contact layer) and a wire layer on the substrate 204. This process is repeated for the wire levels 606 and via levels 604 in the first portion of the interconnect structure 202. In some embodiments, the wire levels 606 and via levels 604 are formed using a plurality of damascene or dual damascene processes. In some embodiments, the interlayer dielectric 602 is or comprises an insulative material, such as silicon dioxide (SiO₂), silicon nitride (Si₃N₄), or the like. In some embodiments, the wires and vias of the plurality of wire levels 606 and the plurality of via levels 604 are or comprise one or more of aluminum, copper, aluminum copper, or the like.

As shown in the cross-sectional view 1000 of FIG. 10, a first masking layer 1004 is formed over the first portion of the interconnect structure 202. In some embodiments, the first masking layer 1004 is formed by depositing (e.g., via a deposition process, a spin-on process, a dipping process, or the like) a photoresist over the substrate 204, then patterning the photoresist using photolithography. After the first masking layer 1004 is formed, a first opening 1002 is formed in the interlayer dielectric 602. In some embodiments, the first opening 1002 is formed using a dry etching process 1006 to etch through layers of the interlayer dielectric 602 and the etch stop layers 902. In some embodiments, the dry etching process 1006 ends after exposing a wire level of the plurality of wire levels 606. The first masking layer 1004 is subsequently removed.

As shown in the cross-sectional view 1100 of FIG. 11, in some embodiments, the capacitor 108 is formed in the first opening 1002. The capacitor 108 formed in the first opening 1002 is an MIM, MOM, or other type of capacitor. In some embodiments, the capacitor 108 is formed by depositing a bottom metal layer, a conformal dielectric layer, and a top metal layer over the first portion of the interconnect structure 202. The bottom metal layer, the conformal dielectric layer, and the top metal layer are etched to remove portions not corresponding to the capacitor 108, resulting in a bottom capacitor metal 1102, a capacitor dielectric 1104, and a top capacitor metal 1106 remaining in the first opening 1002. In some embodiments, a single masking layer is used to in the patterning of the bottom metal layer, the conformal dielectric layer, and the top metal layer. In other embodiments, one or more additional masking layers are used to pattern the capacitor to have two terminals at upper surfaces of the bottom capacitor metal 1102 and the top capacitor metal 1106, or to pattern a wire level 606 concurrent with patterning the bottom capacitor metal 1102. In some embodiments, portions of the capacitor 108 outside of the first opening 1002 are vertically spaced from the wire levels 606 of the first portion of the interconnect structure. After the capacitor 108 is formed, a protective layer 1108 is formed over the capacitor 108.

As shown in the cross-sectional view 1200 of FIG. 12, a second portion of the interconnect structure 202 is formed over the capacitor 108 and the first portion of the interconnect structure 202. In some embodiments, the second portion of the interconnect structure 202 is formed the same way as the first portion of the interconnect structure (see FIG. 9). In some embodiments, the second portion of the interconnect structure 202 comprises the high voltage wire 104. In other embodiments, the high voltage wire 104 is in the first portion of the interconnect structure 202, and a conductive path extending through the first portion and the second portion of the interconnect structure couples the high voltage wire to the capacitor 108.

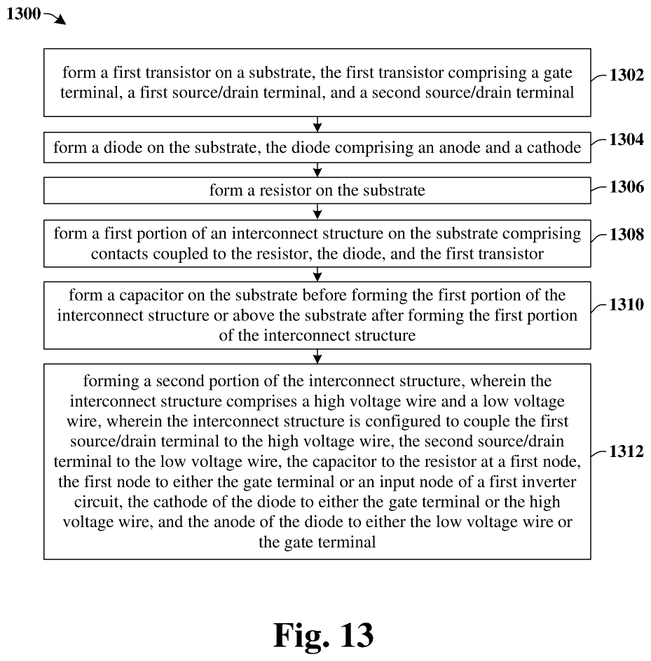

FIG. 13 illustrates a flowchart 1300 of some embodiments of a method of forming an active power clamp with a diode between the gate terminal and a voltage wire. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1302, a first transistor is formed on a substrate, the first transistor comprising a gate terminal, a first source/drain terminal, and a second source/drain terminal. An example of a drawing illustrating this step can be found, for example, in FIG. 8.

At 1304, a diode is formed on the substrate, the diode comprising an anode and a cathode. An example of a drawing illustrating this step can be found, for example, in FIG. 8.

At 1306, a resistor is formed on the substrate. An example of a drawing illustrating this step can be found, for example, in FIG. 8.

At 1308, a first portion of an interconnect structure is formed on the substrate comprising contacts coupled to the resistor, the diode, and the first transistor. An example of a drawing illustrating this step can be found, for example, in FIG. 9.

At 1310, a capacitor is formed either on the substrate before forming the first portion of the interconnect structure or above the substrate after forming the first portion of the interconnect structure. An example of a drawing illustrating this step can be found, for example, in FIGS. 10-11.

At 1312, a second portion of the interconnect structure is formed, wherein the interconnect structure comprises a high voltage wire and a low voltage wire, wherein the interconnect structure is configured to couple the first source/drain terminal to the high voltage wire, the second source/drain terminal to the low voltage wire, the capacitor to the resistor at a first node, the first node to either the gate terminal or an input node of a first inverter circuit, the cathode of the diode to either the gate terminal or the high voltage wire, and the anode of the diode to either the low voltage wire or the gate terminal. An example of a drawing illustrating this step can be found, for example, in FIG. 12.

Some embodiments relate to an integrated device, including: a resistor and capacitor structure coupled in series between a high voltage wire and a low voltage wire, the resistor and capacitor structure having a first node electrically coupled to a resistor and a capacitor; a transistor comprising a first source/drain terminal coupled to the high voltage wire, a second source/drain terminal coupled to the low voltage wire, and a gate terminal; and a diode coupled between the gate terminal and either the high voltage wire or the low voltage wire.

Other embodiments relate to an integrated device, including: a first transistor on a substrate and comprising a gate terminal, a first source/drain terminal, and a second source/drain terminal; an interconnect structure coupled to the gate terminal, the first source/drain terminal, and the second source/drain terminal; a high voltage wire extending through the interconnect structure and coupled to the first source/drain terminal; a low voltage wire extending through the interconnect structure and coupled to the second source/drain terminal; a diode and coupled to the gate terminal by the interconnect structure by the interconnect structure and one of the high voltage wire or the low voltage wire; a resistor coupled to a first node of the interconnect structure and one of the high voltage wire or the low voltage wire; and a capacitor coupled to the first node and the other of the high voltage wire or the low voltage wire, wherein the first node is either coupled to the gate terminal or coupled to a first inverter circuit.

Yet other embodiments relate to a method of forming an integrated device, including: forming a first transistor on a substrate, the first transistor including a gate terminal, a first source/drain terminal, and a second source/drain terminal; forming a diode on the substrate, the diode including an anode and a cathode; forming a resistor on the substrate; forming a capacitor on or above the substrate; and forming a second portion of the interconnect structure, wherein the interconnect structure includes a high voltage wire and a low voltage wire, where the interconnect structure is configured to couple the first source/drain terminal to the high voltage wire, the second source/drain terminal to the low voltage wire, the capacitor to the resistor at a first node, the first node to either the gate terminal or an input node of a first inverter circuit, the cathode of the diode to either the gate terminal or the high voltage wire, and the anode of the diode to either the low voltage wire or the gate terminal.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a resistor and capacitor structure coupled in series between a high voltage wire and a low voltage wire, the resistor and capacitor structure having a first node electrically coupled to a resistor and a capacitor;
a transistor comprising a first source/drain terminal coupled to the high voltage wire, a second source/drain terminal coupled to the low voltage wire, and a gate terminal; and
a diode coupled between the gate terminal and either the high voltage wire or the low voltage wire.

2. The integrated device of claim 1, wherein the gate terminal is electrically coupled to the first node between the resistor and the capacitor.

3. The integrated device of claim 2, wherein the resistor is coupled between the high voltage wire and the first node, and wherein the diode has an cathode coupled to the high voltage wire and a anode coupled to the gate terminal.

4. The integrated device of claim 2, wherein the resistor is coupled between the low voltage wire and the first node, and wherein the diode has an cathode coupled to the gate terminal and a anode coupled to the low voltage wire.

5. The integrated device of claim 1, further comprising a first inverter circuit coupled to the first node.

6. The integrated device of claim 5, wherein the first inverter circuit has an output node coupled to the gate terminal, wherein the resistor is coupled between the high voltage wire and the first node, and wherein the diode has an cathode coupled to the gate terminal and a anode coupled to the low voltage wire.

7. The integrated device of claim 5, further comprising a second inverter circuit coupled to an output node of the first inverter circuit and the gate terminal.

8. The integrated device of claim 7, wherein the resistor is coupled between the high voltage wire and the first node, and wherein the diode has an cathode coupled to the high voltage wire and a anode coupled to the gate terminal.

9. An integrated device, comprising:
a first transistor on a substrate and comprising a gate terminal, a first source/drain terminal, and a second source/drain terminal;
an interconnect structure coupled to the gate terminal, the first source/drain terminal, and the second source/drain terminal;
a high voltage wire extending through the interconnect structure and coupled to the first source/drain terminal;
a low voltage wire extending through the interconnect structure and coupled to the second source/drain terminal;
a diode coupled to the gate terminal and one of the high voltage wire or the low voltage wire by the interconnect structure;
a resistor coupled to a first node of the interconnect structure and one of the high voltage wire or the low voltage wire; and
a capacitor coupled to the first node and the other of the high voltage wire or the low voltage wire, wherein the first node is either coupled to the gate terminal or coupled to a first inverter circuit.

10. The integrated device of claim 9, wherein the first transistor, the resistor, and the diode further comprises:
a channel layer comprising a binary III/V semiconductor material; and
an active layer comprising a ternary III/V semiconductor material.

11. The integrated device of claim 9, wherein the first inverter circuit comprises a second transistor coupled by the interconnect structure to the high voltage wire and a second node, and a third transistor coupled by the interconnect structure to the low voltage wire and the second node.

12. The integrated device of claim 11, wherein the second node is coupled to the gate terminal.

13. The integrated device of claim 9 wherein the diode comprises a high electron mobility transistor (HEMT) with a source/drain terminal coupled to a gate terminal.

14. The integrated device of claim 9, wherein the diode comprises a silicon type diode comprising a region of a first doping type surrounded by a region of a second doping type.

15. A method of forming an integrated device, comprising:
forming a first transistor on a substrate, the first transistor comprising a gate terminal, a first source/drain terminal, and a second source/drain terminal;
forming a diode on the substrate, the diode comprising an anode and a cathode;
forming a resistor on the substrate;
forming a first portion of an interconnect structure on the substrate comprising contacts coupled to the resistor, the diode, and the first transistor;
forming a capacitor either on the substrate before forming the first portion of the interconnect structure or above the substrate after forming the first portion of the interconnect structure; and
forming a second portion of the interconnect structure, wherein the interconnect structure comprises a high voltage wire and a low voltage wire, wherein the interconnect structure is configured to couple the first source/drain terminal to the high voltage wire, the second source/drain terminal to the low voltage wire, the capacitor to the resistor at a first node, the first node to either the gate terminal or an input node of a first inverter circuit, the cathode of the diode to either the gate terminal or the high voltage wire, and the anode of the diode to either the low voltage wire or the gate terminal.

16. The method of claim 15, further comprising:
forming a second transistor and a third transistor concurrently with forming the first transistor, the second transistor and the third transistor forming a portion of the first inverter circuit, wherein the interconnect structure couples a source/drain terminal of the second transistor to a source/drain terminal of the third transistor at an output node, and wherein the output node of the first inverter circuit is coupled either to the gate terminal or to an input node of a second inverter circuit.

17. The method of claim 16, further comprising:
forming a fourth transistor and a fifth transistor concurrently with forming the first transistor, the fourth transistor and the fifth transistor forming a portion of the second inverter circuit, wherein the interconnect structure couples a source/drain terminal of the fourth transistor to a source/drain terminal of the fifth transistor at an output node, and wherein the output node of the second inverter circuit is coupled either to the gate terminal or to an input node of a third inverter circuit.

18. The method of claim 15, wherein the first transistor, the diode, the resistor, and the capacitor are all formed concurrently.

19. The method of claim 18, wherein the first transistor, the diode, the resistor, and the capacitor are formed by:
forming a channel layer comprising a binary III/V semiconductor material or silicon carbide on the substrate;
forming an active layer comprising a ternary III/V semiconductor material on the channel layer;
removing first portions of the active layer and the channel layer, separating second portions of the active layer and the channel layer corresponding to the first transistor, the diode, the resistor, and the capacitor;
forming the first source/drain terminal and the second source/drain terminal of the first transistor, a pair of source/drain terminals for the diode, a pair of source/drain terminals for the resistor, and a source/drain terminal for the capacitor on the second portions of the active layer corresponding to the first transistor, the diode, the resistor, and the capacitor respectively; and
forming the gate terminal of the first transistor, a gate terminal for the diode, and a gate terminal for the capacitor, wherein the gate terminal of the diode and a source/drain terminal of the diode are electrically coupled together.

20. The method of claim 15, further comprising:
forming the first portion of the interconnect structure before forming the capacitor; and
forming the second portion of the interconnect structure after forming the capacitor, wherein the capacitor extends over the resistor, the transistor, and the diode.
